(19) United States
(12) Patent Application Publication
(10) Pub. No.: US 2026/0020475 A1
(43) Pub. Date: Jan. 15, 2026

(54) DISPLAY DEVICE, ELECTRONIC DEVICE INCLUDING THE SAME, METHOD FOR MANUFACTURING WINDOW, AND METHOD FOR MANUFACTURING THE DISPLAY DEVICE

(71) Applicant: Samsung Display Co., LTD., Yongin-si (KR)

(72) Inventors: SEONGJIN HWANG, Yongin-si (KR); BYUNGHOON KANG, Yongin-si (KR); SANGHOON KIM, Yongin-si (KR); SEUNGHO KIM, Yongin-si (KR); JINGYU SIM, Yongin-si (KR); HYUNJI LEE, Yongin-si (KR); TAEHYEOG JUNG, Yongin-si (KR)

(21) Appl. No.: 19/258,284

(22) Filed: Jul. 2, 2025

(30) Foreign Application Priority Data
Jul. 11, 2024 (KR) 10-2024-0091998

(51) Int. Cl. H10K 59/80; G06F 1/16; H10K 71/00; H10K 102/00

(52) U.S. Cl. CPC H10K 59/871; G06F 1/1618; G06F 1/1652; G06F 1/1656; H10K 71/851; H10K 2102/311

(57) ABSTRACT

A display device includes a display panel and a window disposed on the display panel. The window includes a glass substrate including a top surface, a bottom surface facing the top surface in a thickness direction, and a side surface that is extended to the top surface and the bottom surface, a resin layer that covers an entirety of the top surface, the bottom surface, and the side surface of the glass substrate, and a window protective layer disposed on the resin layer.

This application claims priority to Korean Patent Application No. 10-2024-0091998, filed on Jul. 11, 2024, and all the benefits accruing therefrom under 35 U.S.C. § 119, the content of which in its entirety is herein incorporated by reference.

### BACKGROUND

### 1. Field

The disclosure herein relates to a display device, a method for manufacturing a window, and a method for manufacturing the display device using the same.

### 2. Description of the Related Art

The display device provides information to the user by displaying various images on the display screen. Generally, the display device displays information within the allocated screen.

Recently, flexible display devices including flexible display panels that may slide, or fold have also been developed. Unlike rigid display devices, the flexible display devices may be folded, rolled, or bent. Flexible display devices, which takes on various shapes, offer improved portability without being restricted by conventional screen sizes, thereby enhancing user convenience.

### SUMMARY

The disclosure provides a display device with improved product reliability, a method for manufacturing a window included therein, and a method for manufacturing the display device using the same.

An embodiment of the inventive concept provides a display device including: a display panel; and a window disposed on the display panel, where the window includes: a glass substrate including a top surface, a bottom surface facing the top surface in a thickness direction, and a side surface which is extended to the top surface and the bottom surface; a resin layer which covers an entirety of the top surface, the bottom surface, and the side surface of the glass substrate; and a window protective layer disposed on the resin layer.

In an embodiment, the resin layer may include: a first resin layer which covers the top surface of the glass substrate; and a second resin layer which covers the bottom surface and the side surface of the glass substrate.

In an embodiment, the second resin layer may include: a (2-1)-th resin part disposed below the glass substrate to cover the bottom surface of the glass substrate; and a (2-2)-th resin part disposed on a side portion of the glass substrate, and in contact with the side surface of the glass substrate, where at least one portion of the first resin layer contacts the (2-2)-th resin part.

In an embodiment, the first resin layer may include: a (1-1)-th resin part which is disposed on the glass substrate and covers the top surface of the glass substrate; and a (1-2)-th resin part which extends in the thickness direction from the (1-1)-th resin part, and of which one side surface contacts at least a portion of the (2-2)-th resin part.

In an embodiment, the (1-2)-th resin part may be spaced apart from the (2-1)-th resin part in a cross-section.

In an embodiment, a material contained in the first resin layer is the same as that contained in the second resin layer.

In an embodiment, a material contained in the first resin layer may be different from that contained in the second resin layer.

In an embodiment, a first thickness of the glass substrate may be greater than a second thickness of the first resin layer.

In an embodiment, the resin layer may include at least one of urethane resin, epoxy resin, polyimide resin, polyester resin, polyether resin, acrylate resin, or acrylonitrile-butadiene-styrene resin.

In an embodiment, the window may further include a fingerprint-resistant layer disposed on the window protective layer.

In an embodiment, the display device may further include an optical layer disposed on the display panel and the window.

In an embodiment of the inventive concept, a method for manufacturing a window include: forming a mother-sheet window including a plurality of windows which are arranged in a first direction and a second direction intersecting the first direction and are individually divided by a first division line; and cutting the mother-sheet window along the first division line to divide the plurality of windows from each other, where the forming the mother-sheet window include: providing a first mother-sheet glass substrate including a preliminary glass substrate divided along the first division line; irradiating laser onto the first mother-sheet glass substrate to correspond to the first division line, thereby defining a first groove, to form a second mother-sheet glass substrate; forming a first mother-sheet resin layer on the second mother-sheet glass substrate; etching the second mother-sheet glass substrate from a lower side to define a second groove corresponding to the first division line, thereby forming a third mother-sheet glass substrate; and forming a second mother-sheet resin layer on a lower portion of the third mother-sheet glass substrate.

In an embodiment, the forming the second mother-sheet glass substrate may further include: chemically treating a top surface of the second mother-sheet glass substrate to increase a size of the first groove.

In an embodiment, the chemically treating the top surface of the second mother-sheet glass substrate to increase the size of the first groove may include: increasing in strength of the top surface of the second mother-sheet glass substrate.

In an embodiment, the forming the third mother-sheet glass substrate may further include chemically treating a bottom surface of the third mother-sheet glass substrate to increase a size of the second groove.

In an embodiment, the chemically treating the bottom surface of the third mother-sheet glass substrate to increase the size of the second groove may include: increasing in strength of the bottom surface of the third mother-sheet glass substrate.

In an embodiment, the method may further include after the forming the second mother-sheet resin layer, forming a mother-sheet window protective layer on the first mother-sheet resin layer.

In an embodiment of the inventive concept, a method for manufacturing a display device including a display module including a light-emitting element and a window disposed on the display module, the method including: forming a mother-sheet window including a plurality of windows arranged in a first direction and a second direction intersecting the first direction, being divided by a first division line; and cutting the mother-sheet window along the first division line to divide each of the plurality of windows, where the forming the mother-sheet window includes: providing a first mother-sheet glass substrate including a preliminary glass substrate divided along the first division line; irradiating laser onto the first mother-sheet glass substrate to correspond to the first division line, thereby defining a first groove, to form a second mother-sheet glass substrate; forming a first mother-sheet resin layer on the second mother-sheet glass substrate; etching the second mother-sheet glass substrate from a lower side to define a second groove corresponding to the first division line, thereby forming a third mother-sheet glass substrate; and forming a second mother-sheet resin layer on a lower portion of the third mother-sheet glass substrate.

In an embodiment, the method may further include after dividing the plurality of windows, coupling display module to a lower portion of the window.

In an embodiment, the method may further include after forming the mother-sheet window, providing a mother-sheet display substrate including a plurality of display module which are divided through the first division line; and coupling the mother-sheet display module to a lower portion of the mother-sheet window to form a mother-sheet substrate; and cutting the mother-sheet substrate along the first division line to divide the plurality of display devices into each other.

### BRIEF DESCRIPTION OF THE DRAWINGS

The accompanying drawings are included to provide a further understanding of the inventive concept and are incorporated in and constitute a part of this specification. The drawings illustrate embodiments of the inventive concept and, together with the description, serve to explain principles of the inventive concept. In the drawings:

FIG. 1A is a block diagram of an embodiment of an electronic device according to the inventive concept. FIG. 1B is schematic views of various embodiments of electronic devices according to the inventive concept.

FIG. 1C is a perspective view of an embodiment of a display device according to the inventive concept.

FIGS. 2A to 2D are views illustrating a state in which the display device shown in FIG. 1C is folded.

FIG. 3A is a perspective view illustrating an embodiment of a state in which the display device is unfolded according to the inventive concept.

FIGS. 3B and 3C are views illustrating a state in which the display device shown in FIG. 3A is folded.

FIG. 4 is an exploded perspective view of an embodiment of the display device according to the inventive concept.

FIG. 5 is a cross-sectional view of the display device taken along a cutting line I-I′ shown in FIG. 4.

FIGS. 6A to 6C are cross-sectional views of an embodiment of a window according to the inventive concept.

FIG. 7A is a flowchart illustrating a method for manufacturing the window according to the inventive concept.

FIG. 7B is a flowchart illustrating an embodiment of a portion of the method for manufacturing the window according to the inventive concept.

FIG. 8A is a perspective view illustrating an embodiment of a portion of the method for manufacturing the window according to the inventive concept.

FIGS. 8B to 8I are cross-sectional views illustrating an embodiment of a portion of the method for manufacturing the window according to the inventive concept; and

FIGS. 9, 10A, and 10B are cross-sectional views illustrating an embodiment of a portion of the method for manufacturing the window according to the inventive concept.

### DETAILED DESCRIPTION

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. The thickness and the ratio and the dimension of the element are exaggerated for effective description of the technical contents. As used herein, the term “and/or” includes any and all combinations of one or more of the associated listed items.

It will be understood that when an element or layer is referred to as being “on”, “connected to” or “coupled to” another element or layer, it may be directly on, connected or coupled to the other element or layer or intervening elements or layers may be present.

Like numbers refer to like elements throughout. The thickness and the ratio and the dimension of the element are exaggerated for effective description of the technical contents. As used herein, the term “and/or” includes any and all combinations of one or more of the associated listed items.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

It will be understood that, although the terms first, second, etc. may be used herein to describe various elements, components, regions, layers and/or sections, these should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the drawing figures. It will be understood that the spatially relative terms are intended to encompass different orientations of the device in use or operation in addition to the orientation depicted in the drawing figures.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the inventive concept will be explained in detail with reference to the accompanying drawings.

A display device according to an embodiment may be applied to various electronic devices. The electronic device according to an embodiment may include the display module described above, and may further include a module or device having additional functions in addition to the display module.

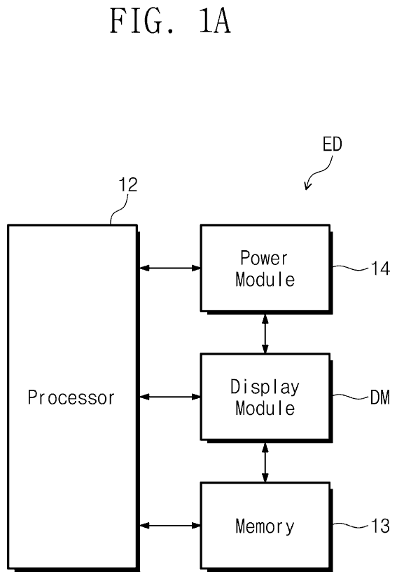

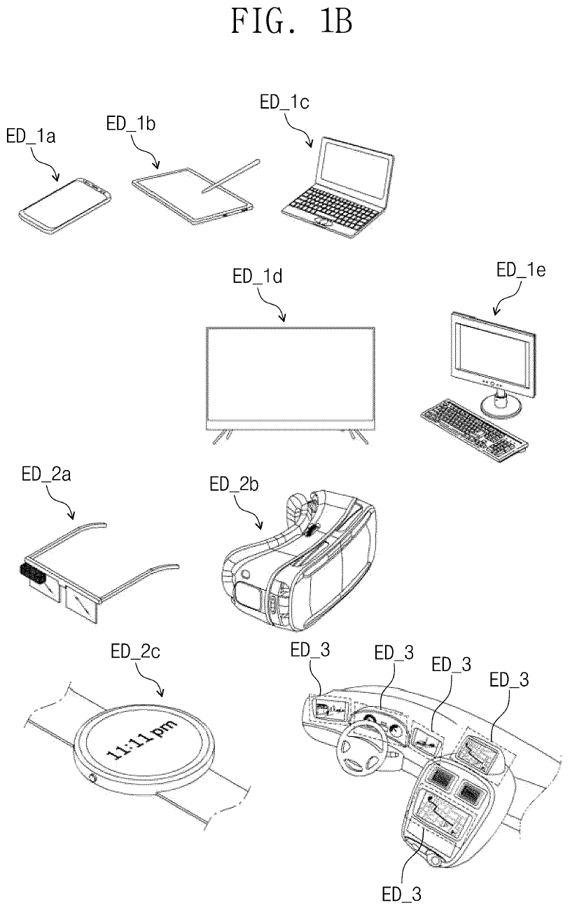

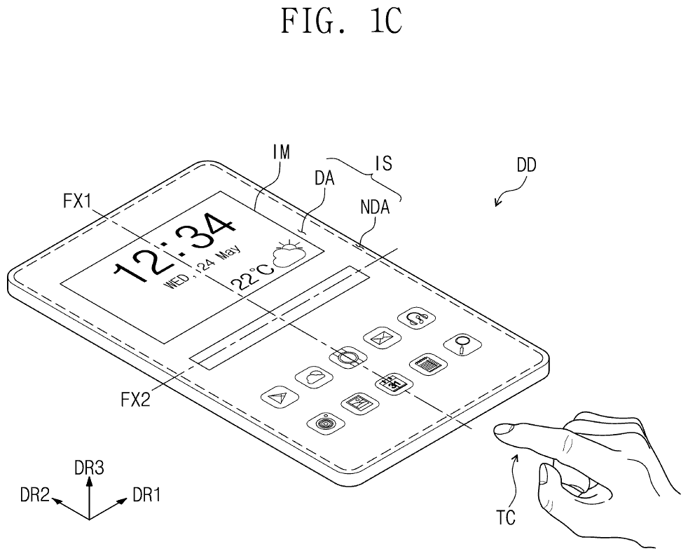

FIG. 1A is a block diagram of an embodiment of an electronic device according to the inventive concept. Referring to FIG. 1A, an electronic device ED according to an embodiment may include a display module DM, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information required for the operation of the processor 12 or the display module DM. When the processor 12 executes an application stored in the memory 15, image data signals and/or input control signals are transmitted to the display module DM, and the display module DM may process the received signal and output image information through a display screen.

The power module 14 may include a power supply module such as a power adapter or a battery device, and a power conversion module that converts power supplied by the power supply module to generate power required for the operation of the electronic device ED.

At least one of the components of the electronic device ED described above may be included in the display device according to the above-described embodiments. In addition, some of the individual modules functionally included in one module may be included in the display device, and others may be separately provided from the display device. For example, the display device may include a display module DM, and the processor 12, the memory 13, and the power module 14 may be provided in the form of other devices within the electronic device ED, rather than the display device.

FIG. 1B is schematic views of various embodiments of electronic devices according to the inventive concept.

Referring to FIG. 1B, various electronic devices to which the display device according to embodiments is applied may include an electronic device for displaying images, such as a smart phone ED_1a, a tablet PC ED_1b, a laptop ED_1c, a TV ED_1d, and a desk monitor ED_1e, a wearable electronic device including a display module such as a smart glasses ED_2a, a head mounted display ED_2b, and a smart watch ED_2c, and a vehicle electronic device ED_3 including a display module such as a center information display (CID) and a room mirror display disposed on an instrument panel, a center fascia, or a dashboard of a vehicle. In addition, these devices are merely provided as embodiments, and other electronic devices may be employed as long as not departing from the inventive concept.

FIG. 1C is a perspective view of an embodiment of a display device according to the inventive concept.

Referring to FIG. 1C, a display device DD may be a device that is activated according to an electrical signal. The display device DD may include various embodiments. In an embodiment, the display device DD may be used in relatively large electronic devices such as televisions, monitors, or outdoor billboards, as well as in medium and relatively small electronic devices such as personal computers, laptop computers, personal digital assistants, car navigation units, gaming consoles, portable electronic devices, and cameras. In this embodiment, the display device DD is a smartphone, for example.

The display device DD has a quadrangular shape, e.g., rectangular shape with a short side in a first direction DR1 and a long side in a second direction DR2, which intersects the first direction DR1. However, the shape of the display device DD is not limited thereto, and display devices of various shapes may be provided.

The display device DD may be a foldable display device. Specifically, the display device DD in an embodiment of the inventive concept may be folded based on a folding axis extending in a predetermined direction. Hereinafter, a state in which the display device DD is the unfolded and flat will be defined as a first state (i.e., a non-folding state), and a state in which the display device DD is folded based on the folding axis will be defined as a second state (i.e., a folding state). The folding axis may be an axis of rotation generated when the display device DD is folded and be defined by a mechanical structure of the display device DD.

The folding axis may extend in the first direction DR1 or the second direction DR2. In an embodiment of the inventive concept, a folding axis extending in the second direction DR2 is defined as a first folding axis FX1, and a folding axis extending in the first direction DR1 is defined as a second folding axis FX2. The display device DD may include any one of the first and second folding axes FX1 and FX2. That is, the display device DD may be folded based on either the first axis FX1 or the second folding axis FX2.

As shown in FIG. 1C, the display device DD may display an image IM on a display surface IS that is parallel to both the first direction DR1 and the second direction DR2. The display surface IS on which the image IM is displayed, may correspond to a front surface of the display device DD. A direction perpendicular to the display surface IS, that is, a thickness direction of the display device DD, may be also referred to as a third direction DR3. The display device DD may display the image IM toward the third direction DR3.

The display surface IS of the display device DD may be divided into a plurality of regions. On the display surface IS of the display device DD, a display area DA and a non-display area NDA may be defined.

The display area DA may be an area on which the image IM is displayed, and the user views the image IM through the display area DA. The display area DA may have a quadrangular shape, e.g., rectangular shape. The non-display area NDA is an area next (adjacent) to the display area DA on which the image IM is not displayed. A bezel area of the display device DD may be defined by the non-display area NDA. In one embodiment of the inventive concept, the non-display area NDA may surround the display area DA. Accordingly, the display area DA may have a shape that is substantially defined by the non-display area NDA. However, this is only an illustrative embodiment, and the non-display area NDA may be disposed next (adjacent) to only one side of the display area DA, or the non-display area NDA may be omitted.

The display device DD according to the inventive concept may detect a user's input TC applied from the outside. The user's input TC may include various types of external inputs, such as a part of the user's body, light, heat, or pressure. In this embodiment, the user's input TC is illustrated as being applied by the user's hand to the front surface. However, this is only an illustrative embodiment, and as described above, various types of user's input TC may be provided. Also, the display device DD may detect the user's input TC applied to a side surface of a rear surface of the display device DD according to the structure of the display device DD, and not be limited to an embodiment.

The display device DD may activate the display surface IS to display the image IM while simultaneously detecting the user's input TC. In this embodiment, an area on which the user's input TC is detected is illustrated as being provided on the display area DA that displays the image IM. However, this is only an illustrative embodiment, and the area on which the user's input TC is detected may be provided on the non-display area NDA or throughout the entirety of the area of the display surface IS.

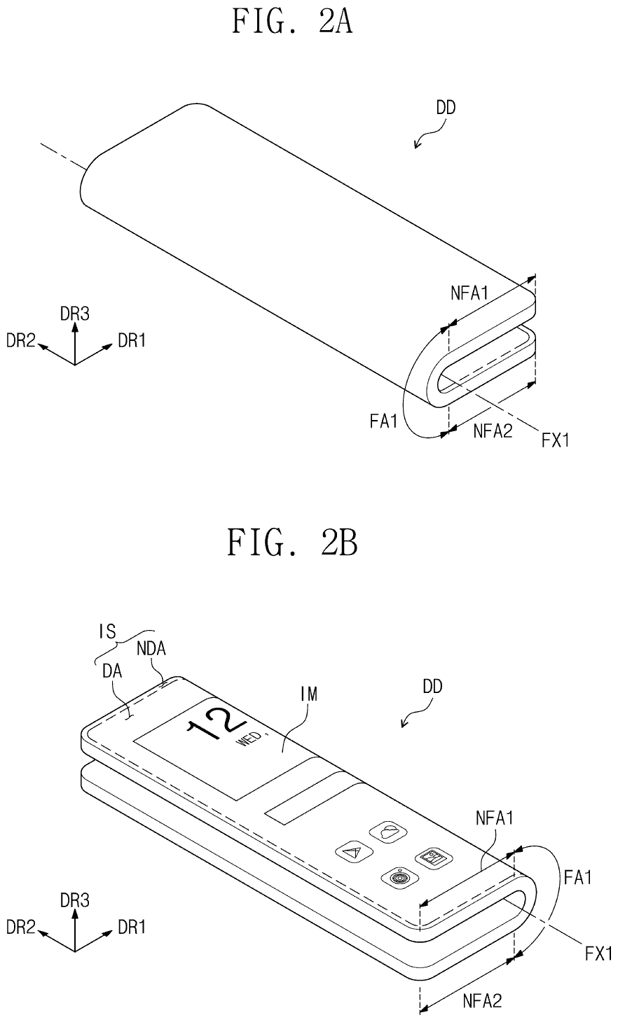

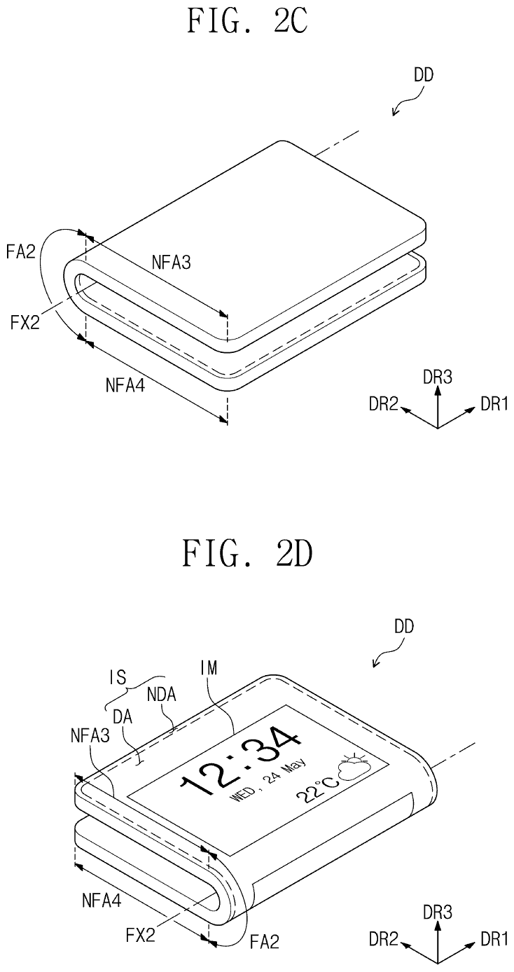

FIGS. 2A to 2D are drawings illustrating a state in which the display device shown in FIG. 1C is folded.

FIG. 2A is a view illustrating a state in which the display device DD shown in FIG. 1C is inner-folded along the first folding axis FX1, and FIG. 2B is a view illustrating a state in which the display device DD shown in FIG. 1C is outer-folded along the first folding axis FX1.

FIG. 2C is a view illustrating a state in which the display device DD shown in FIG. 1C is inner-folded along the second folding axis FX2, and FIG. 2D is a view illustrating a state in which the display device DD shown in FIG. 1C is outer-folded along the second folding axis FX2.

Referring to FIGS. 2A to 2D, the display device DD may be a foldable display device. The display device DD may be folded based on a folding axis extending in a predetermined direction, e.g., the first folding axis FX1 or the second folding axis FX2.

Referring to FIGS. 2A and 2B, a plurality of areas may be defined on the display device DD according to an operation mode. The plurality of areas may be divided into a folding area FA1 and at least one non-folding area NFA1 or NFA2. The folding area FA1 may be defined between the two non-folding areas NFA1 and NFA2.

The folding area FA1 is an area that folds based on the first folding axis FX1 and substantially defines a curvature. Here, the first folding axis FX1 may extend along the second direction DR2, which is a longitudinal direction of the display device DD. The folding area FA1 is defined as an area that folds along the first folding axis FX1 and extends in the second direction DR2.

In one embodiment of the inventive concept, the non-folding areas NFA1 and NFA2 may include a first non-folding area NFA1 and a second non-folding area NFA2. The first non-folding area NFA1 is next (adjacent) to one side of the folding area FA1 in the first direction DR1, and the second non-folding area NFA2 is next (adjacent) to an opposite side of the folding area FA1 in the first direction DR1.

The display device DD may be either inner-folded or outer-folded. In-folding is defined as folding such that display surfaces of different non-folding areas NFA1 and NFA2 face each other, while out-folding is defined as folding such that the display surfaces of different non-folding areas NFA1 and NFA2 face outward.

Here, in-folding refers to folding so that the display surfaces IS face each other, and out-folding refers to folding so that the rear surfaces of the display device DD face each other.

As shown in FIG. 2A, the display device DD may be inner-folded so that the display surfaces IS (refer to FIG. 1C) of the first non-folding area NFA1 and the second non-folding area NFA2 face each other. The display device DD may be inner-folded by rotating the first non-folding area NFA1 clockwise along the first folding axis FX1. To in-fold the display device DD such that the first non-folding area NFA1 and the second non-folding area NFA2 are aligned, the first folding axis FX1 may be defined at the center of the display device DD in the first direction DR1.

Referring to FIG. 2B, the display device DD may be outer-folded based on the first folding axis FX1. The display device DD may display the image IM when the display surfaces of the first non-folding area NFA1 and the second non-folding area NFA2 are exposed outward. Additionally, the display surface of the folding area FA1, which is exposed outward, may also display the image IM. As shown in FIG. 1C, the display device DD may display the image IM in an opened state. The first non-folding area NFA1, the second non-folding area NFA2, and the folding area FA1 may each display images providing independent information or may display parts of one image providing one information.

The display device DD may be manufactured to have both in-folding and out-folding states or may be manufactured to have either an in-folding or an out-folding state.

Referring to FIGS. 2C and 2D, the display device DD may be inner-folded or outer-folded based on the second folding axis FX2. The second folding axis FX2 may extend along the first direction DR1, which is in a short axis direction of the display device DD.

A plurality of areas may be defined on the display device DD according to the operation mode. The plurality of areas may be divided into a folding area FA2 and at least one non-folding area NFA3 or NFA4. The folding area FA2 may be defined between the two non-folding areas NFA3 and NFA4.

The folding area FA2 is an area that folds based on the second folding axis FX2 and substantially defines a curvature. The folding area FA2 is defined as an area that folds along the second folding axis FX2 and extends in the first direction DR1.

In one embodiment of the inventive concept, the non-folding areas NFA3 and NFA4 may include a first non-folding area NFA3 and a second non-folding area NFA4 The first non-folding area NFA3 is next (adjacent) to one side of the folding area FA2 in the second direction DR2, and the second non-folding area NFA4 is next (adjacent) to an opposite side of the folding area FA2 in the second direction DR2.

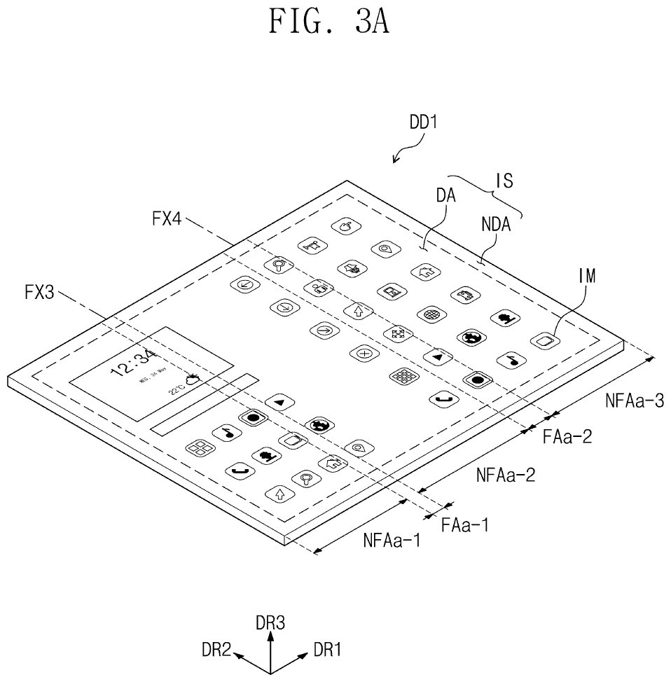

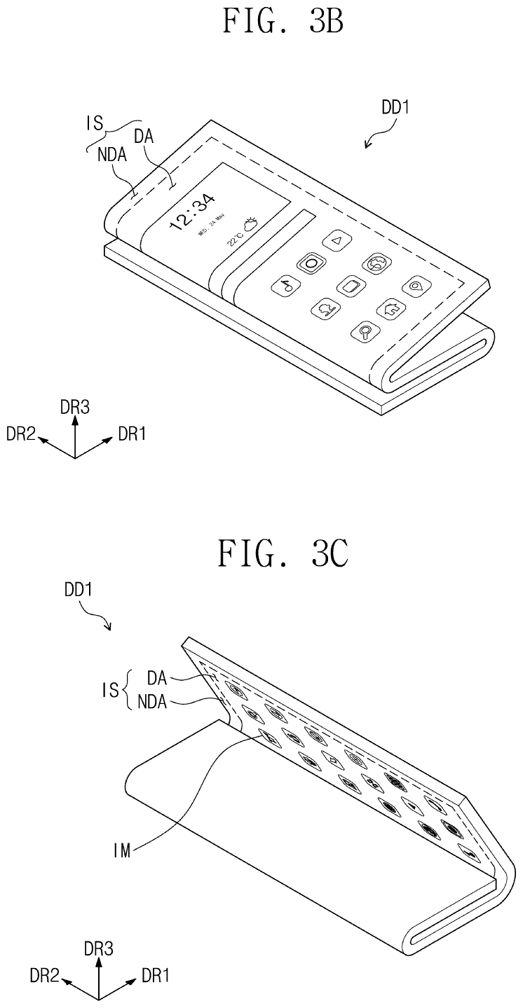

FIG. 3A is a perspective view illustrating an embodiment of a state in which a display device is opened according to the inventive concept; FIGS. 3B and 3C are drawings illustrating a state in which the display device shown in FIG. 3A is multi-folded.

Referring to FIGS. 3A to 3C, a display device DD1 may be a foldable display device. A plurality of folding areas may be defined on the display device DD1. The display device DD1 may include a plurality of folding areas FAa-1 and FAa-2, and a plurality of non-folding areas NFAa-1, NFAa-2, and NFAa-3. In one embodiment of the inventive concept, the display device DD1 may include a first folding area FAa-1, a second folding area FAa-2, a first non-folding area NFAa-1, a second non-folding area NFAa-2, and a third non-folding area NFAa-3. Along the first direction DR1, the first folding area FAa-1 is disposed between the first non-folding area NFAa-1 and the second non-folding area NFAa-2, while the second folding area FAa-2 is disposed between the second non-folding area NFAa-2 and the third non-folding area NFAa-3. Although two folding areas FAa-1 and FAa-2 and three non-folding areas NFAa-1, NFAa-2, and NFAa-3 are illustrated in an embodiment, the number of folding areas FAa-1 and FAa-2 and non-folding areas NFAa-1, NFAa-2, and NFAa-3 is not limited thereto and may be increased.

Referring to FIGS. 3A and 3B, the first folding area FAa-1 may be folded based on a third folding axis FX3, which is parallel to the second direction DR2. The first folding area FAa-1 may be inner-folded such that a display surface of the second non-folding area NFAa-2 faces a display surface of the first non-folding area NFAa-1. The second folding area FAa-2 may be folded based on a fourth folding axis FX4, which is parallel to the second direction DR2. The second folding area FAa-2 may be outer-folded such that a rear surface of the second non-folding area NFAa-2 and a rear surface of the third non-folding area NFAa-3 face each other, and a display surface of the third non-folding area NFAa-3 faces outward.

Referring to FIGS. 3A and 3C, the first folding area FAa-1 may be folded based on the third folding axis FX3, which is parallel to the second direction DR2. The display device DD1 may be inner-folded such that a display surface of first non-folding area NFAa-1 is disposed inside, and a display surface of the second non-folding area NFAa-2 faces the display surface of the first non-folding area NFAa-1. The second folding area FAa-2 may be folded based on a fourth folding axis FX4, which is parallel to the second direction DR2. The display device DD1 may be inner-folded such that a rear surface of the first non-folding area NFAa-1 and the display surface of the third non-folding area NFAa-3 may face each other.

In an embodiment of the inventive concept, the out-folding and in-folding operations may occur simultaneously, or only one of the out-folding or in-folding operations may occur.

Although the multi-folded state of the display device DD1 is shown in FIGS. 3B and 3C, it is not limited thereto, and the display device DD1 may have various folding configurations.

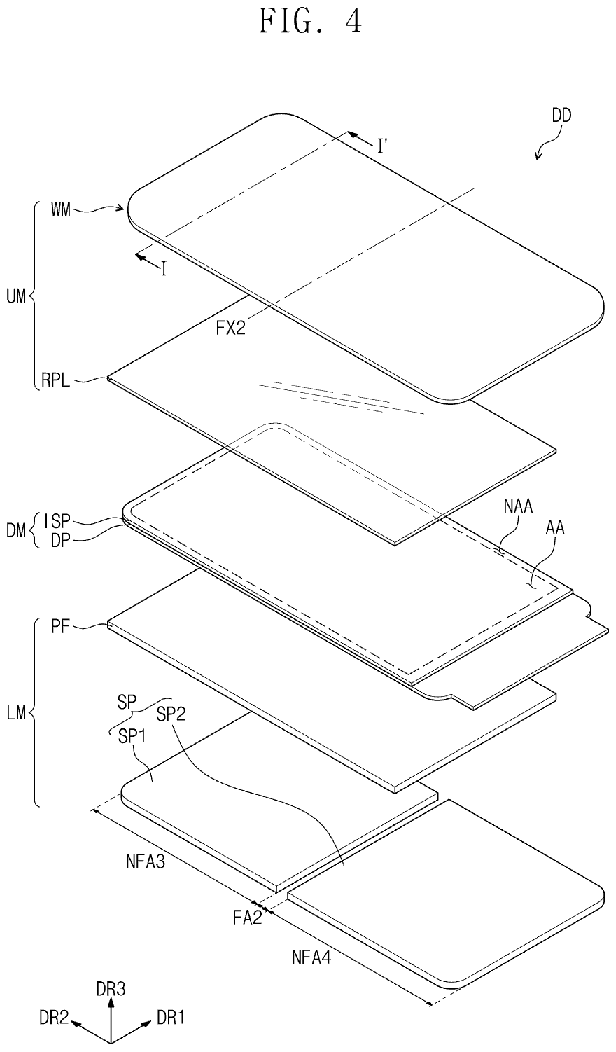

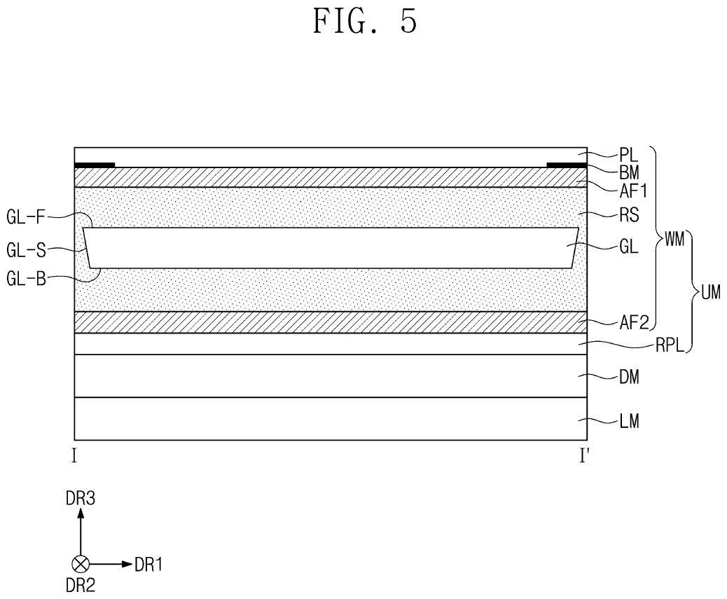

FIG. 4 is an exploded perspective view of an embodiment of the display device according to the inventive concept, and FIG. 5 is a cross-sectional view of the display device taken along a cutting line I-I′ shown in FIG. 4.

Referring to FIGS. 4 and 5, the display device DD in an embodiment of the inventive concept may include a display module DM for displaying images, an upper module UM disposed on the display module DM, and a lower module LM disposed below the display module DM. The display module DM may constitute a portion of the display device DD, and particularly, images may be generated by the display module DM.

The display module DM may include a display panel DP and an input sensing unit ISP. The display panel DP in an embodiment of the inventive concept may be a light-emitting display panel, and it is not particularly limited thereto. In an embodiment, the display panel DP may be an organic light-emitting display panel, an inorganic light-emitting display panel, or a quantum dot light-emitting display panel, for example. A light-emitting layer of the organic light-emitting display panel may include organic light-emitting materials, and a light-emitting layer of the inorganic light-emitting display panel may include inorganic light-emitting materials. A light-emitting layer of the quantum dot light-emitting display panel may include quantum dots and quantum rods. Hereinafter, the display panel DP will be described as an organic light-emitting display panel.

The display panel DP may be a flexible display panel. Accordingly, the display panel DP may be entirely rolled up or folded or opened along the second folding axis FX2.

The input sensing unit ISP may be directly disposed on the display panel DP. In an embodiment of the inventive concept, the input sensing unit ISP may be disposed on the display panel DP through a continuous process. That is, when the input sensing unit ISP is directly disposed on the display panel DP, an adhesive film is not disposed between the input sensing unit ISP and the display panel DP. However, the inventive concept is not limited thereto. The adhesive film may be disposed between the input sensing unit ISP and the display panel DP. In this case, the input sensing unit ISP is not manufactured through a continuous process performed with the display panel DP, but rather, it is manufactured through a divide process and then fixed to a top surface of the display panel DP via an adhesive film.

The display panel DP generates images, while the input sensing unit ISP obtains coordinate information for the user's input (e.g., touch events).

The upper module UM may include a window WM disposed on the display module DM. The window WM may include an optically transparent insulating material. Accordingly, the image generated by the display module DM may easily be recognized by the user as it passes through the window WM. The window WM may include a glass substrate GL, a resin layer RS, a window protective layer PL, and a light-blocking part BM.

The glass substrate GL may include or consist of glass material. The glass substrate GL may include a top surface GL-F, a bottom surface GL-B, and a side surface GL-S. The top surface GL-F and the bottom surface GL-B refer to two opposing surfaces of the glass substrate GL, e.g., the two surfaces that face each other in the third direction DR3. In the glass substrate GL, a surface next (adjacent) to an anti-reflective layer RPL or the display module DM in the third direction DR3 may be the bottom surface GL-B, while a surface next (adjacent) to the window protective layer PL may be the top surface GL-F. The side surface GL-S may refer to a surface that is extended to the top surface GL-F and the bottom surface GL-B of the glass substrate GL. The side surface GL-S may be perpendicular to the top surface GL-F or the bottom surface GL-B, or may define an oblique angle with respect to a normal line of the top surface GL-F or the bottom surface GL-B. The side surface GL-S may have a first angle with respect to the bottom surface GL-B, and the first angle may be between about 90 and about 120 degrees. In an embodiment, when manufacturing the glass substrate GL in an embodiment of the inventive concept, an etching process using an etchant may be included, resulting in the first angle between the side surface GL-S and the bottom surface GL-B of the glass substrate GL being greater than about 90 degrees.

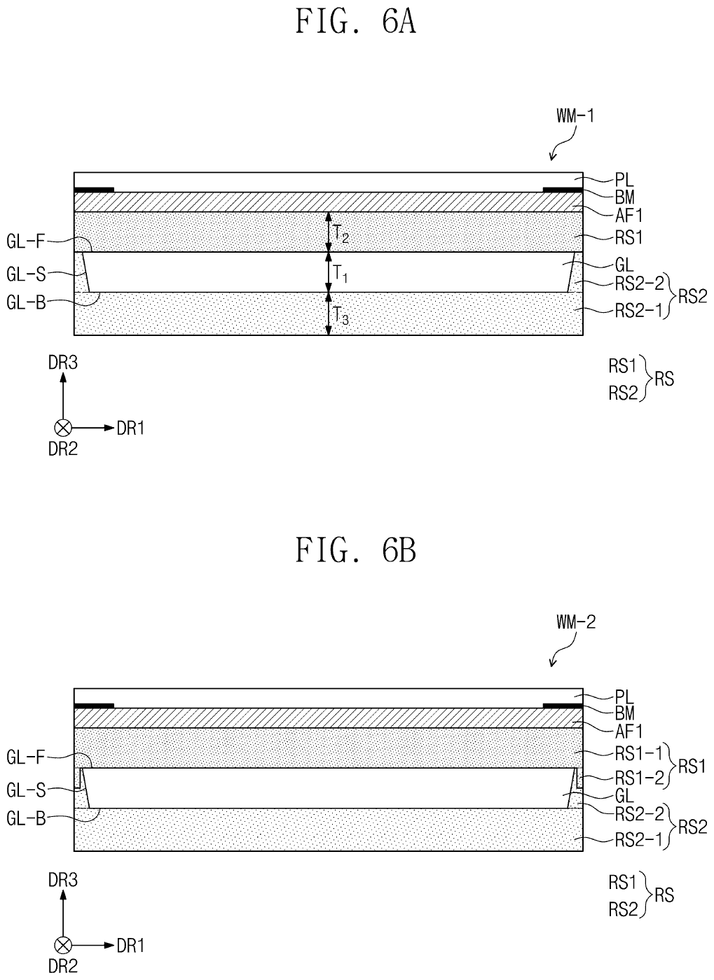

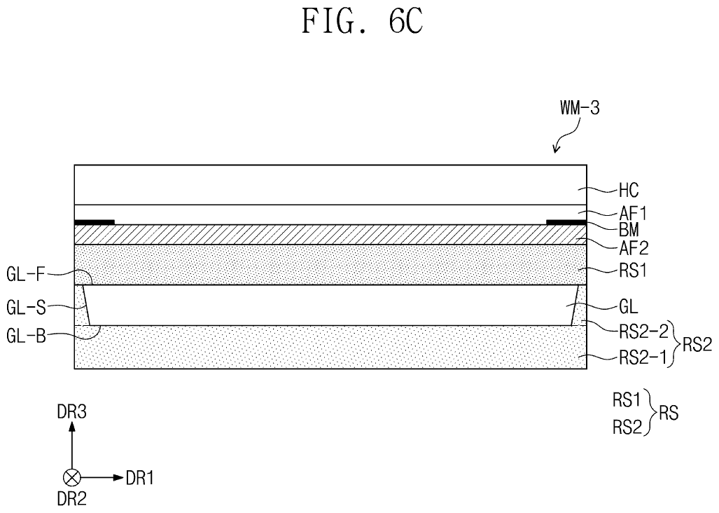

The resin layer RS may cover the entirety of the surface of the glass substrate GL. The resin layer RS may contact all the surfaces of the glass substrate GL, including the top surface GL-F, the bottom surface GL-B, and the side surface GL-S. Since the window WM in an embodiment of the inventive concept includes a resin layer RS that surrounds the entirety of the surface of the glass substrate GL, the strength of the window WM may be improved. A detailed description of the resin layer RS will be provided below in FIG. 6A.

The light-blocking part BM may be disposed on a bottom surface of the window protective layer PL. The light-blocking part BM may overlap the non-display area NDA of the display device DD (refer to FIG. 1C). The light-blocking part BM may be provided including organic or inorganic light-blocking materials that include black pigments or dyes. However, the disclosure is not limited thereto, and the light-blocking part BM may have a color other than black.

The window protective layer PL may be provided on the glass substrate GL. The window protective layer PL may be provided on the resin layer RS. The window protective layer PL may function to protect the glass substrate GL from external impacts. The window protective layer PL may include synthetic resin material. In one embodiment of the inventive concept, the window protective layer PL may include at least one selected from urethane resin, epoxy resin, polyester resin, polyether resin, acrylate resin, acrylonitrile-butadiene-styrene (“ABS”) resin, and rubber. Specifically, the window protective layer PL may include at least one of phenylene, polyethylene terephthalate (“PET”), polyimide (“PI”), polyamide (“PAI”), polyethylene naphthalate (“PEN”), or polycarbonate (“PC”).

The window WM may further include a first window adhesive layer AF1 and a second window adhesive layer AF2. The first window adhesive layer AF1 may be disposed between the glass substrate GL and the window protective layer PL to attach the window protective layer PL to the glass substrate GL. The second window adhesive layer AF2 may couple the window WM to a component disposed below the window WM. In an embodiment, the second window adhesive layer AF2 may be disposed between the window WM and the display module DM to attach the window WM to the display module DM, for example. In an alternative embodiment, the second window adhesive layer AF2 may be disposed between the window WM and the anti-reflective layer RPL to attach the window WM to the anti-reflective layer RPL. The first window adhesive layer AF1 and the second window adhesive layer AF2 may include an optically transparent adhesive material. In an embodiment, each of the first window adhesive layer AF1 and the second window adhesive layer AF2 may include a pressure-sensitive adhesive (“PSA”), an optical clear adhesive (“OCA”), or an optical clear resin (“OCR”), for example. However, the embodiments of the inventive concept are not limited thereto, and when desired, the first window adhesive layer AF1 and the second window adhesive layer AF2 may be omitted, and each component may be directly disposed without a divide adhesive layer.

The window WM may be folded or unfolded around the second folding axis FX2. In other words, the shape of the window WM may change along with the deformation of the display module DM. The window WM allows the image from the display module DM to be transmitted while simultaneously mitigating external impacts, preventing the display module DM from being damaged or malfunctioning as a result of external impacts. External impact refers to an external force, such as pressure or stress, which may cause defects in the display module DM.

Additionally, the upper module UM may further include one or more optical layers disposed between the display module DM and the window WM. In an embodiment of the inventive concept, the optical layer may be an anti-reflective layer RPL that prevents external light reflections.

The anti-reflective layer RPL may prevent elements constituting the display module DM from being visible from the outside due to external light incident through the front of the display device DD. The anti-reflective layer RPL may include a retarder and a polarizer. The retarder may be a film type or a liquid crystal coating type and may include a λ/2 retarder and/or a λ/4 retarder. The polarizer may also be a film type or a liquid crystal coating type. The film type may include a stretched synthetic resin film, while the liquid crystal coating type may include liquid crystals arranged in a predetermined pattern. The retarder and polarizer may be implemented as a single polarizing film. A functional layer may further include a protective film disposed on or below the anti-reflective layer RPL.

The display module DM may display images according to an electrical signal and transmit/receive information about external input. The display module DM may include an active area AA and a peripheral area NAA. The active area AA may be defined as an area on which the image provided by the display module DM is emitted.

The peripheral area NAA is next (adjacent) to the active area AA. In an embodiment, the peripheral area NAA may surround the active area AA. However, this is only an illustrative embodiment, and the peripheral area NAA may be defined in various shapes and not be limited to a particular embodiment. In an embodiment, the active area AA of the display module DM may correspond to at least one portion of the display area DA (refer to FIG. 1C).

The lower module LM is disposed on a rear surface of the display module DM and includes a support plate SP that supports the display module DM. The support plate SP may include the number of support plates corresponding to that of the non-folding areas NFA3 and NFA4. In one embodiment of the inventive concept, the support plate SP may include a first support plate SP1 and a second support plate SP2, which is disposed apart from the first support plate SP1.

The first and second support plates SP1 and SP2 may be disposed corresponding to the first and second non-folding areas NFA3 and NFA4, respectively. The first support plate SP1 is disposed corresponding to the first non-folding area NFA3 of the display module DM, and the second support plate SP2 is disposed corresponding to the second non-folding area NFA4 of the display module DM. Each of the first and second support plates SP1 and SP2 may include metal material or plastic material.

When the display module DM is in the flat first state, the first and second support plates SP1 and SP2 are spaced apart from each other in the second direction DR2. When the display module DM is in the second state in which the display module DM is folded based on the second folding axis FX2, the first and second support plates SP1 and SP2 are spaced apart from each other in the second direction DR3.

The first and second support plates SP1 and SP2 may be spaced apart corresponding to the folding area FA2. The first and second support plates SP1 and SP2 may partially overlap the folding area FA2. That is, a distance between the first and second support plates SP1 and SP2 in the second direction DR2 may be smaller than the width of the folding area FA2.

The support plate SP may further include a connecting module to connect the first and second support plates SP1 and SP2. The connecting module may include a hinge module or a multi-joint module.

Although the support plate SP is provided with two support plates SP1 and SP2 in the drawings, it is not limited thereto. That is, when a plurality of second folding axes FX2 are provided, the support plate SP may include a plurality of support plates that are divided based on the plurality of second folding axes FX2. Additionally, the support plate SP may be provided as an integrated structure without being divided into the first and second support plates SP1 and SP2. In this case, a bending part may be provided in the support plate SP corresponding to the folding area FA2. The bending part may define an opening defined by passing through the support plate SP or a groove recessed from one surface of the support plate SP.

The lower module LM may further include a protective film PF disposed between the display module DM and the support plate SP. The protective film PF may be disposed below the display module DM to protect the rear surface of the display module DM. The protective film PF may include a synthetic resin film, e.g., a polyimide film or a polyethylene terephthalate film. However, this is merely exemplary, and the protective film PF is not limited to the examples.

Although not shown, the lower module LM may further include a first adhesive film disposed between the protective film PF and the display module DM, and a second adhesive film disposed between the protective film PF and the support plate SP. The protective film PF may be attached to the rear surface of the display module DM by the first adhesive film. The second adhesive film may include a first sub-adhesive film and a second sub-adhesive film. The first sub-adhesive film may be disposed between the first support plate SP1 and the protective film PF, and the second sub-adhesive film may be disposed between the second support plate SP2 and the protective film PF. The first and second sub-adhesive films may be spaced apart from each other with the folding area FA2 therebetween. In an embodiment, each of the first and second adhesive films may include a pressure-sensitive adhesive (“PSA”), an optical clear adhesive (“OCA”), or an optical clear resin (“OCR”), for example.

Hereinafter, the window WM in an embodiment of the inventive concept will be described in detail with reference to the accompanying drawings.

FIGS. 6A to 6C are cross-sectional views of an embodiment of a window according to the inventive concept; FIGS. 6A to 6C illustrate the components of the window WM in more detail as shown in FIG. 5.

Referring to FIGS. 6A to 6C, each of windows WM-1, WM-2, and WM-3 includes a glass substrate GL including a top surface GL-F, a bottom surface GL-B, and a side surface GL-S, and a resin layer RS that covers all of the top surface GL-F, bottom surface GL-B, and side surfaces GL-S.

The resin layer RS may include an organic material. The resin layer RS may include at least one of urethane resin, epoxy resin, polyimide resin, polyester resin, polyether resin, acrylate resin, or ABS resin. The modulus of the resin layer RS may range from about 1 kilopascal (kPa) to about 5 gigapascals (GPa). In an embodiment, the modulus of the resin layer RS may range from about 1 kPa to about 5000 kPa, for example. However, the material and properties of the resin layer RS are not limited to the above-described range, and the resin layer RS may be selected without limitation as long as it enhances the strength of the windows WM-1, WM-2, and WM-3.

The resin layer RS may include a first resin layer RS1 and a second resin layer RS2. The first resin layer RS1 may refer to covering the top surface GL-F of the glass substrate GL, while the second resin layer RS2 may refer to covering the bottom surface GL-B and side surfaces GL-S of the glass substrate GL.

The second resin layer RS2 may include a (2-1)-th resin part RS2-1 and a (2-2)-th resin part RS2-2. The (2-1)-th resin part RS2-1 is disposed below the glass substrate GL and may cover the bottom surface GL-B. The (2-1)-th resin part RS2-1 may extend longitudinally in the first direction DR1 or the second direction DR2 along the bottom surface GL-B. The (2-1)-th resin part RS2-1 may be spaced apart from the first resin layer RS1 in the cross-section, with the (2-2)-th resin part RS2-2 or the glass substrate GL therebetween.

The (2-2)-th resin part RS2-2 may be disposed on a side of the glass substrate GL and may cover the bottom surface GL-B. The (2-2)-th resin part RS2-2 may extend longitudinally in the 3rd direction DR3 along the side surface GL-S. One side of the (2-2)-th resin part RS2-2 may contact the side surface GL-S of the glass substrate GL, while the opposite side facing the one side may be exposed to the outside of the windows WM-1, WM-2, and WM-3. Thus, the side surface of the glass substrate GL may not be exposed to the outside of the windows WM-1, WM-2, and WM-3. The (2-2)-th resin part RS2-2 may contact at least one portion of the first resin layer RS1. A bottom of the 1st resin layer RS1 may contact the top surface GL-F of the glass substrate GL or a top surface of the (2-2)-th resin part RS2-2.

The materials included in the first resin layer RS1 and the second resin layer RS2 may be same as each other or different from each other. A first thickness T₁ of the glass substrate GL may be relatively thicker compared to a second thickness T₂ of the first resin layer RS1 and a third thickness T₃ of the second resin layer RS2. The ratio of the first thickness T₁ of the glass substrate GL to the second thickness T₂ of the first resin layer RS1 may be about 0.01 or more. In an embodiment, the ratio of the first thickness T₁ of the glass substrate GL to the second thickness T₂ of the first resin layer RS1 may be about 0.5 or more, for example. The second thickness T₂ of the first resin layer RS1 and the third thickness T₃ of the second resin layer RS2 may be the same or different from each other.

Referring to FIG. 6B, the first resin layer RS1 may include a (1-1)-th resin part RS1-1 and a (1-2)-th resin part RS1-2. The (1-1)-th resin part RS1-1 may be disposed on the glass substrate GL and may cover the top surface GL-F. The (1-1)-th resin part RS1-1 may extend longitudinally in the first direction DR1 or the second direction DR2 along the top surface GL-F.

The (1-2)-th resin part RS1-2 may extend in the opposite direction of the third direction DR3 from the (1-1)-th resin part RS1-1. The (1-2)-th resin part RS1-2 may extend from a bottom surface of the (1-1)-th resin part RS1-1 toward the (2-2)-th resin part RS2-2. In an embodiment, the (1-1)-th resin part RS1-1 is constituted by a first portion overlapping the glass substrate GL in a plan view and a second portion overlapping the (2-2)-th resin part RS2-2 in a plan view. The (1-2)-th resin part RS1-2 may extend in the opposite direction of the third direction DR3 from a bottom surface of the second portion. One side surface of the (1-2)-th resin part RS1-2 may contact the (2-2)-th resin part RS2-2. The (1-2)-th resin part RS1-2 may be spaced apart from the (2-1)-th resin part RS2-1 in a cross-section. In FIG. 6B, the (1-2)-th resin part RS1-2 is shown as being exposed to the outside of the window WM-2, but it is not limited thereto. According to the method for manufacturing the window that will be described later, the (1-2)-th resin part RS1-2 may be disposed between the (2-2)-th resin part RS2-2 and may not be exposed to the outside of the window WM-2. The (1-2)-th resin part RS1-2 may also contact a portion of the side surface GL-S of the glass substrate GL.

Referring to FIG. 6C, the window may further include a functional layer disposed on the window protective layer PL. In an embodiment, the window WM-3 may include a fingerprint-resistant layer HC disposed on the window protective layer PL, for example. The fingerprint-resistant layer HC provides anti-fingerprint functionality, enhancing the usability of the window WD to the users. In an embodiment, the fingerprint-resistant layer HC may be a functional layer in which anti-fingerprint material is added to a hard coating material. The fingerprint-resistant layer HC may include a fluorine-including or consisting of compound. In an embodiment, the fingerprint-resistant layer HC may include a perfluoropolyether (“PFPE”) compound, for example. In an alternative embodiment, the fingerprint-resistant layer HC may include a silane compound including or consisting of perfluoropolyether. The fingerprint-resistant layer HC may have a thickness ranging from about 10 nanometers (nm) to about 40 nm. The fingerprint-resistant layer HC may be formed by at least one of an electron beam (E-beam) deposition process, a thermal deposition process, or a sputtering process. However, the embodiments of functional layers disposed on the window protective layer PL are not limited thereto and may take various shapes as desired.

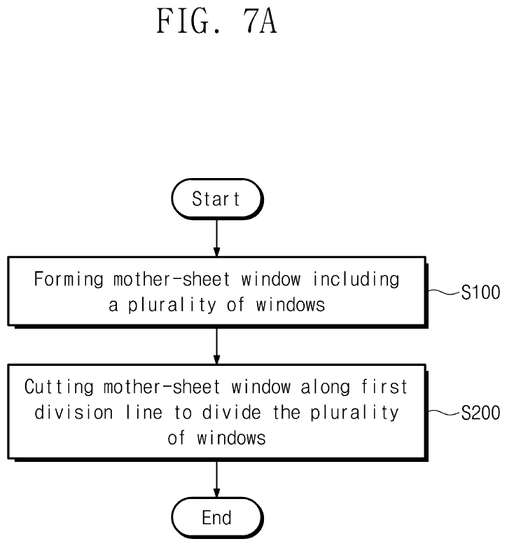

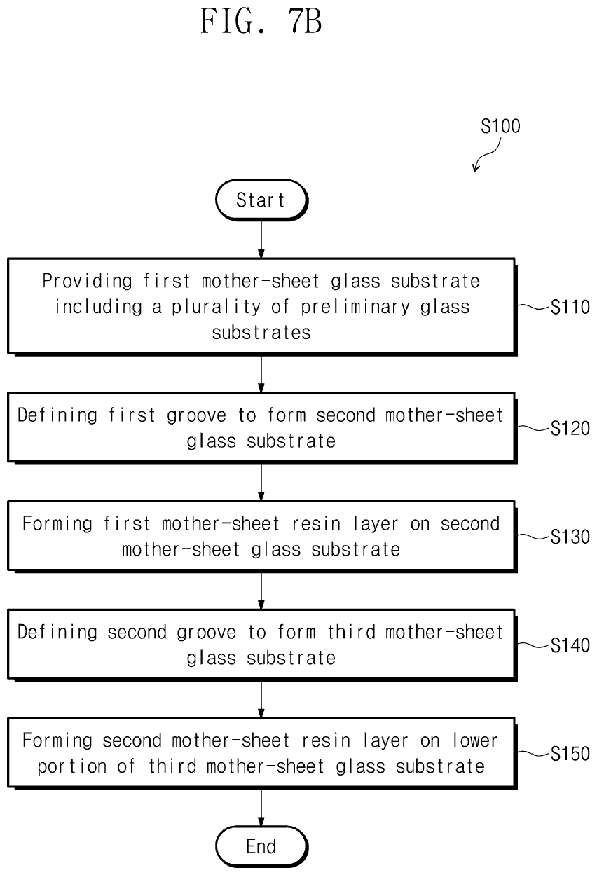

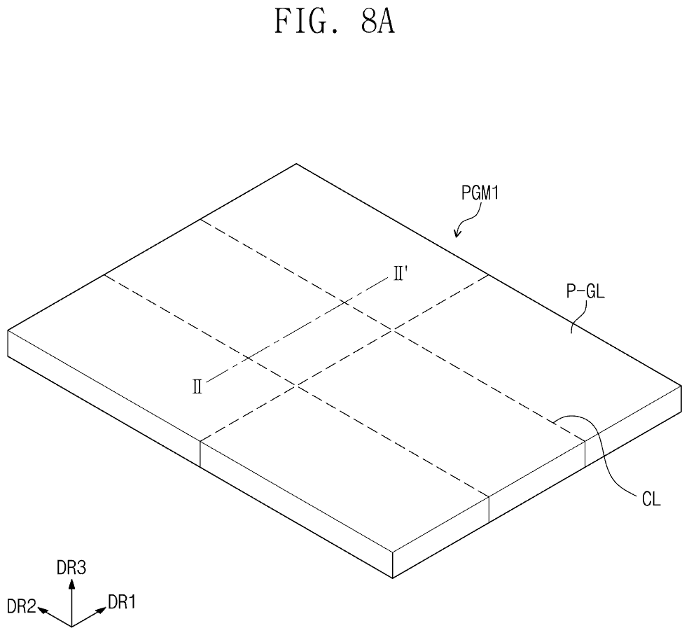

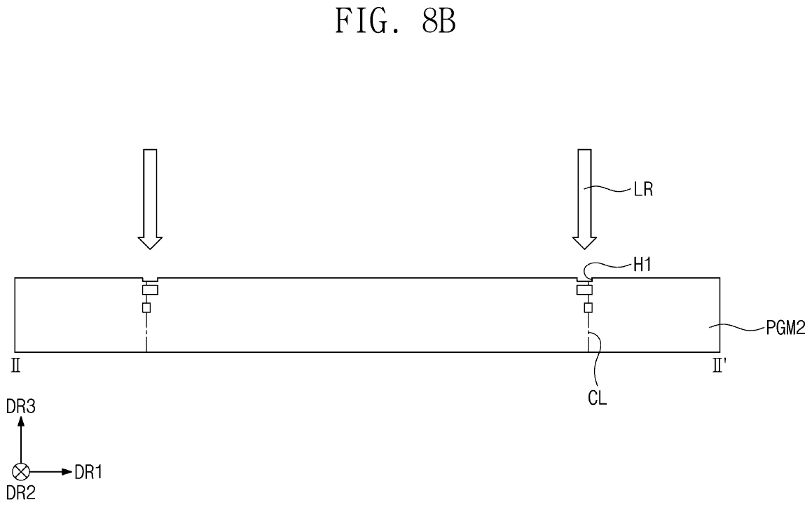

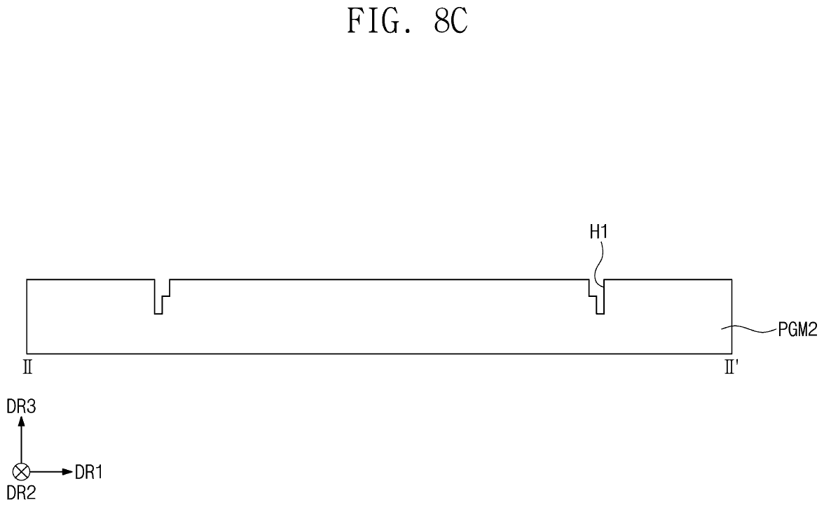

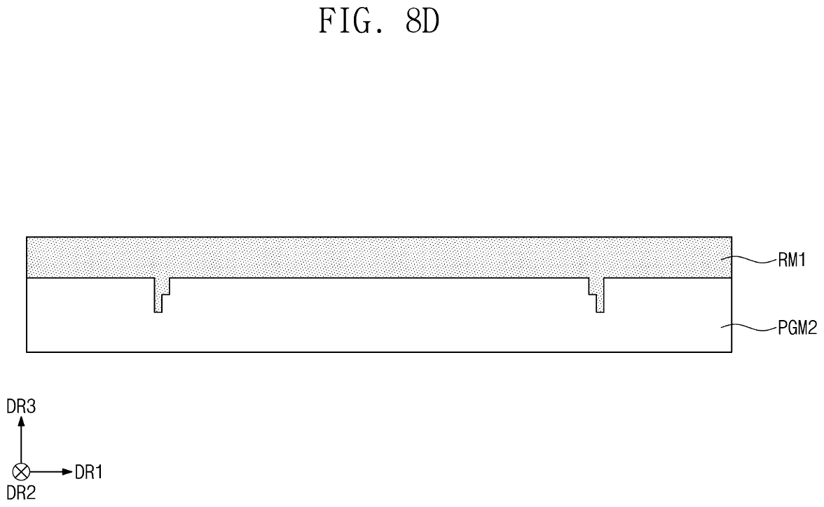

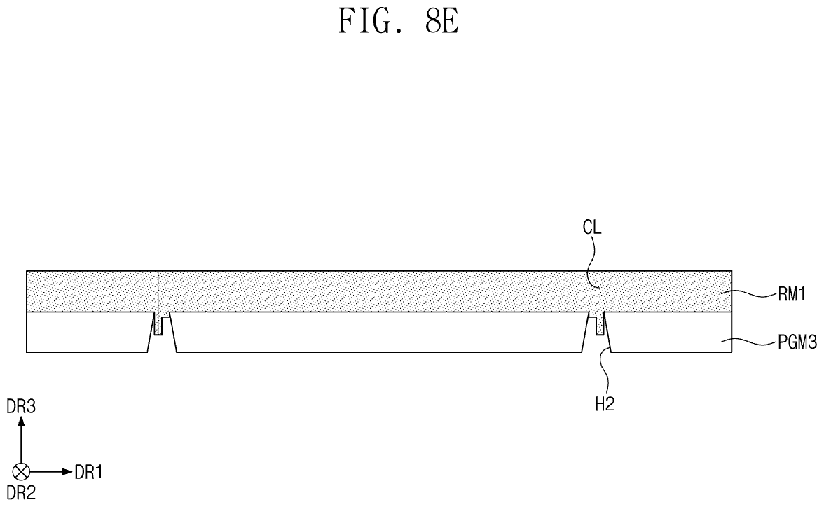

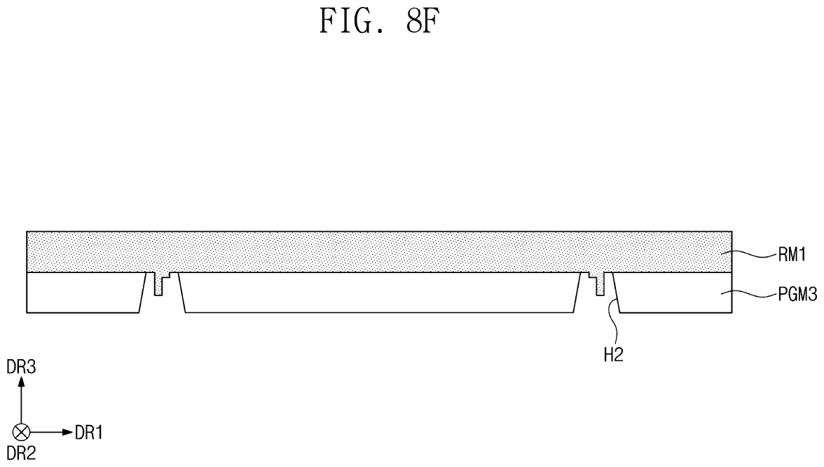

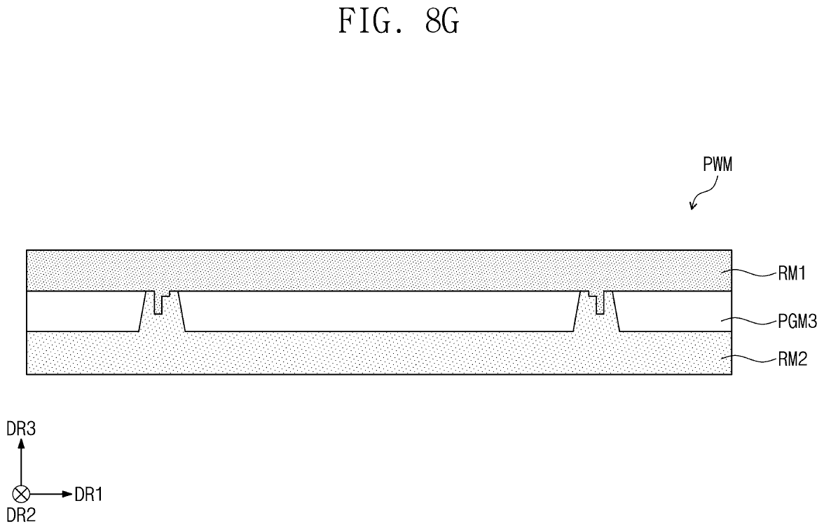

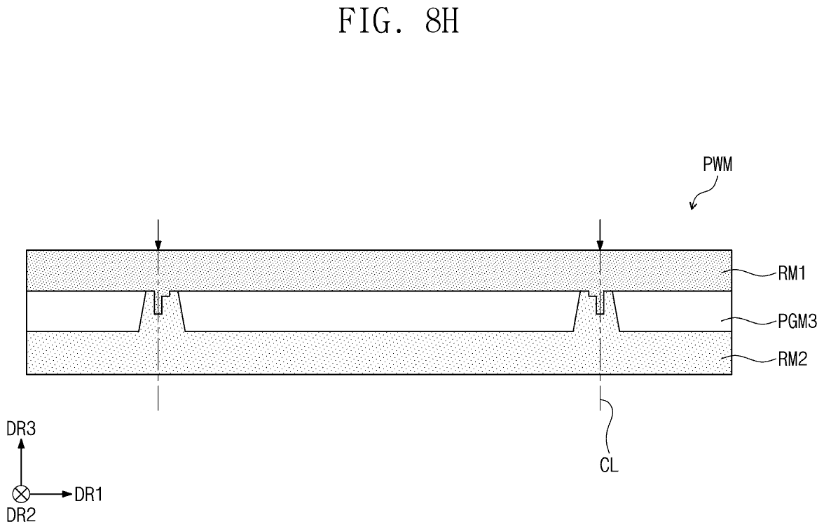

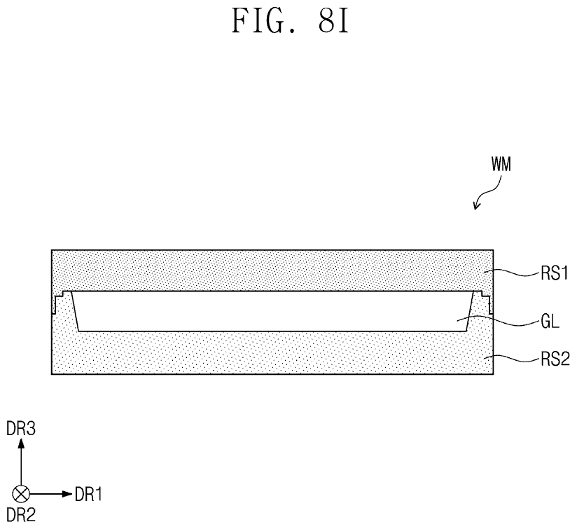

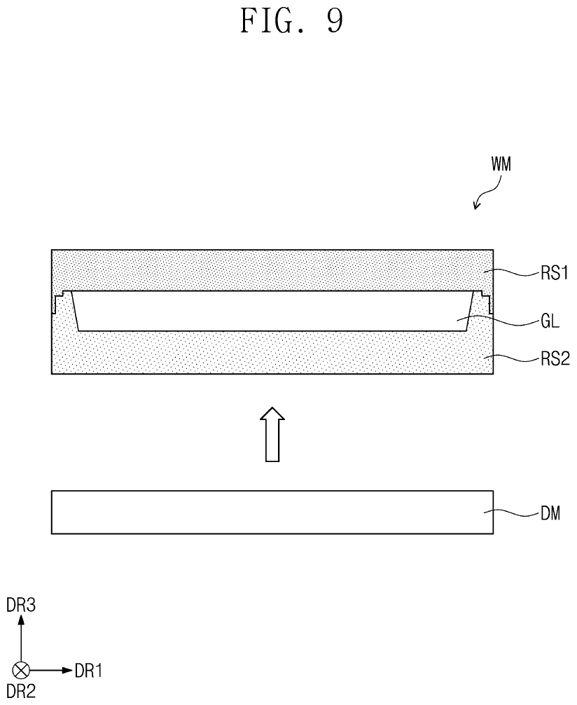

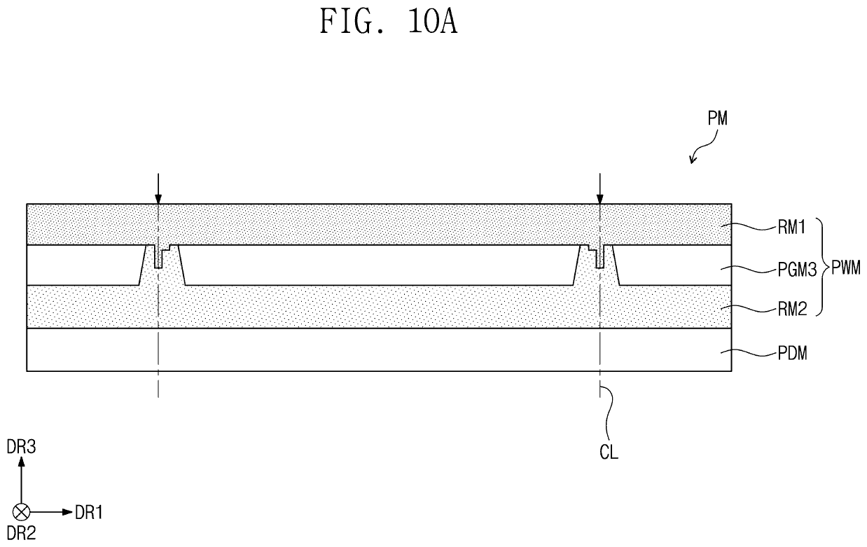

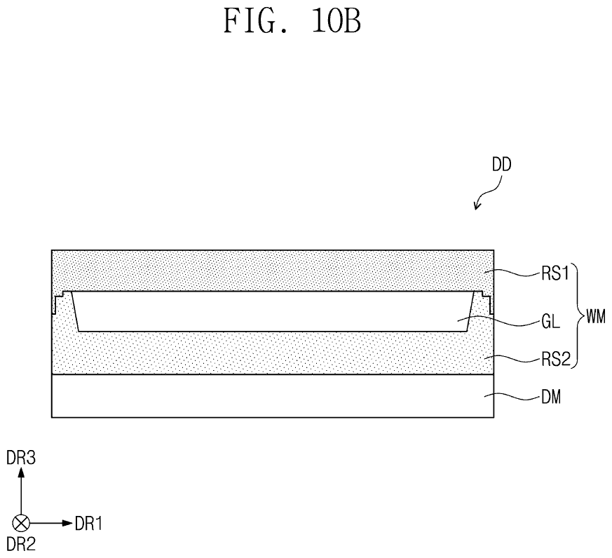

FIG. 7A is a flowchart of an embodiment of a method for manufacturing a window according to the inventive concept. FIG. 7B is a flowchart illustrating an embodiment of a portion of the method for manufacturing the window according to the inventive concept. FIG. 8A is a perspective view illustrating an embodiment of a portion of the method for manufacturing the window according to the inventive concept. FIGS. 8B to 8I are cross-sectional views illustrating an embodiment of a portion of the method for manufacturing the window according to the inventive concept. FIGS. 9, 10A, and 10B are cross-sectional views illustrating an embodiment of a portion of the method for manufacturing the window according to the inventive concept. In describing the method for manufacturing the window and the method for manufacturing the display device in an embodiment of the inventive concept, the same reference numerals are used for components identical to those previously described, and detailed descriptions are omitted.

Referring to FIG. 7A, a method for manufacturing a window in an embodiment of the inventive concept includes forming a mother-sheet window including a plurality of windows (S100) and cutting the mother-sheet window along a first division line to divide the plurality of windows (S200). Referring to FIG. 7B, the forming of the mother-sheet window including the plurality of windows (S100) in the method for manufacturing the window in an embodiment of the inventive concept includes: providing a first mother-sheet glass substrate including a plurality of preliminary glass substrates (S110), forming a second mother-sheet glass substrate by defining a first groove (S120), forming a first mother-sheet resin layer on the second mother-sheet glass substrate (S130), forming a third mother-sheet glass substrate by defining a second groove (S140), and forming a second mother-sheet resin layer on a lower portion of the third mother-sheet lass substrate (S150).

FIGS. 8A to 8G are schematic views illustrating an embodiment of the forming of the mother-sheet window including the plurality of windows (S100) in the method for manufacturing the window according to the inventive concept. FIG. 8A is a schematic view illustrating the providing of the first mother-sheet glass substrate including the plurality of preliminary glass substrates (S110). FIGS. 8B and 8C are schematic views illustrating the forming of the second mother-sheet glass substrate by defining the first groove (S120). FIGS. 8B and 8C are cross-sections corresponding to a cutting line II-II′ shown in FIG. 8A. Hereinafter, FIGS. 8D to 8H illustrate cross-sections corresponding to FIGS. 8B and 8C according to the order of the method for manufacturing the window. FIG. 8D is a schematic view illustrating the forming of the first mother-sheet resin layer on the second mother-sheet glass substrate (S130), and FIGS. 8E and 8F are schematic views illustrating the forming of the third mother-sheet glass substrate by defining the second groove (S140). FIG. 8G is a schematic view illustrating the forming of the second mother-sheet resin layer on the lower portion of the third mother-sheet glass substrate (S150). FIGS. 8H and 8I schematically illustrate the cutting of the mother-sheet window along the first division line to divide the plurality of windows (S200).

Referring to FIGS. 7A and 8A to 8G, the method for manufacturing the window in an embodiment of the inventive concept includes forming a mother-sheet window PWM including a plurality of windows (S100).

Referring to FIGS. 7B and 8A, the forming of the mother-sheet window (S100) in an embodiment of the inventive concept includes providing a first mother-sheet glass substrate PGM1 (S110).

The first mother-sheet glass substrate PGM1 may include a plurality of preliminary glass substrates P-GL. The plurality of preliminary glass substrates P-GL may be arranged in the first direction DR1 and the second direction DR2 in a plan view. The plurality of preliminary glass substrates P-GL may be divided by a first division line CL. In describing the method for manufacturing the window in an embodiment of the inventive concept and the method for manufacturing the display device in an embodiment of the inventive concept, a description of multiple windows or multiple display devices may be described later. Here, the first division line CL may refer to an imaginary division line or division plane that is parallel to the first direction DR1 and the second direction DR2, dividing multiple windows, multiple display devices, or multiple intermediate components (e.g., a plurality of preliminary glass substrates P-GL) into individual units.

Referring to FIGS. 7B and 8A to 8C, the forming of the mother-sheet window (S100) in an embodiment of the inventive concept includes forming a second mother-sheet glass substrate PGM2 by defining a first groove H1 (S120).

The forming of the second mother-sheet glass substrate PGM2 (S120) includes irradiating an intense light, e.g., a laser LR, onto the first mother-sheet glass substrate PGM1. The laser LR may be irradiated to correspond to the first division line CL. As the laser LR is irradiated onto the first mother-sheet glass substrate PGM1, the first groove H1 may be defined in a top surface of the first mother-sheet glass substrate PGM1. The first groove H1 may be defined along the first division line CL. The first grooves H1 may be provided in plural with respect to the third direction DR3. In the forming of the second mother-sheet glass substrate PGM2, the first groove H1 may be provided in plural depending on the characteristics such as the intensity, irradiation time, or wavelength range of the irradiated laser LR.

The forming of the second mother-sheet glass substrate PGM2 (S120) may further include chemically treating a top surface of the second mother-sheet glass substrate PGM2 to increase a size of the first groove H1. Accordingly, the chemically treating of the top surface of the second mother-sheet glass substrate PGM2 to increase a size of the first groove H1 may uniformly etch the top surface of the second mother-sheet glass substrate PGM2, thereby removing fine cracks existing on the surface. The chemically treating of the top surface of the second mother-sheet glass substrate PGM2 to increase a size of the first groove H1 may include a healing process. Through this process, the strength of the top surface of the second mother-sheet glass substrate PGM2 may be relatively increased.

The top surface of the second mother-sheet glass substrate PGM2 may be chemically treated using an etchant. In an embodiment, the top surface of the second mother-sheet glass substrate PGM2 may be chemically treated with sulfuric acid (SO₂), nitric acid (NO₂), or hydrofluoric acid (“HF”), for example. However, the method for chemically treating the second mother-sheet glass substrate PGM2 is not limited thereto and may be designed using various methods through the healing process.

The size of the first groove H1 may be increased with respect to the first to third directions DR3. In an embodiment, as each of the plurality of first grooves H1 increases in size and the plurality of first grooves H1 merge together, for example. Thus, the first groove H1 may increase from a spot shape to form a line shape in a cross-section.

Referring to FIGS. 7B and 8D, the forming of the mother-sheet window (S100) in an embodiment of the inventive concept includes forming a first mother-sheet resin layer RM1 on the second mother-sheet glass substrate PGM2 (S130).

The first mother-sheet resin layer RM1 may be formed on the second mother-sheet glass substrate PGM2. A portion of the first mother-sheet resin layer RM1 may be filled into the first groove H1 (refer to FIGS. 8B and 8C). The forming of the first mother-sheet resin layer RM1 may be performed through a large-area coating process. In an embodiment, the forming of the first mother-sheet resin layer RM1 may be carried out by applying the resin through processes such as bar coating, slot-die coating, spray coating, or screen printing, for example. In an alternative embodiment, the forming of the first mother-sheet resin layer RM1 may be carried out by attaching a film including or consisting of resin.

Referring to FIGS. 7B, 8E and 8F, the forming of the mother-sheet window (S100) in an embodiment of the inventive concept includes forming a third mother-sheet glass substrate PGM3 by defining a second groove H2 (S140).

The forming of the third mother-sheet glass substrate PGM3 may include etching the second mother-sheet glass substrate PGM2 from a lower side. The second mother-sheet glass substrate PGM2 may be etched from the lower side in the opposite direction of the third direction DR3, thereby forming the third mother-sheet glass substrate PGM3. As a result, the thickness of the third mother-sheet glass substrate PGM3 may be relatively less than that of the second mother-sheet glass substrate PGM2. The third mother-sheet glass substrate PGM3 may be formed through a slimming process performed on the second mother-sheet glass substrate PGM2. While the slimming process may be carried out using an etchant, the disclosure is not limited thereto.

As the second mother-sheet glass substrate PGM2 is etched from the lower side, a second groove H2 may be defined in a bottom surface of the third mother-sheet glass substrate PGM3. The second groove H2 may be defined along the first division line CL. In an embodiment, when the second mother-sheet glass substrate PGM2 is etched using an etchant, the etching rate of the second mother-sheet glass substrate PGM2 next (adjacent) to the first division line CL may be relatively higher due to the portion of the first mother-sheet resin layer RM1 filled into the first groove H1 (refer to FIGS. 8B and 8C), for example. As a result, the second groove H2 may be defined along the first division line CL.

The forming of the third mother-sheet glass substrate PGM3 (S120) may further include chemically treating the bottom surface of the third mother-sheet glass substrate PGM3 to increase a size of the second groove H2. Accordingly, the chemically treating of the bottom surface of the third mother-sheet glass substrate PGM3 to increase a size of the second groove H2 may uniformly etch the bottom surface of the third mother-sheet glass substrate PGM3, thereby removing fine cracks existing on the surface of the third mother-sheet glass substrate PGM3. The chemically treating of the bottom surface of the third mother-sheet glass substrate PGM3 to increase a size of the second groove H2 may include a healing process.

Through this process, the strength of the bottom surface of the third mother-sheet glass substrate PGM3 may be relatively increased.

The bottom surface of the third mother-sheet glass substrate PGM3 may be chemically treated using an etchant. In an embodiment, the bottom surface of the third mother-sheet glass substrate PGM3 may be chemically treated with sulfuric acid (SO2), nitric acid (NO2), or hydrofluoric acid (HF), for example. However, the method for chemically treating the third mother-sheet glass substrate PGM3 is not limited thereto and may be designed using various methods through the healing process.

Referring to FIGS. 7B and 8G, the forming of the mother-sheet window (S100) in an embodiment of the inventive concept includes forming a second mother-sheet resin layer RM2 on the third mother-sheet glass substrate PGM3 (S150).

The second mother-sheet resin layer RM2 may be formed on a lower portion the third mother-sheet glass substrate PGM3. A portion of the second mother-sheet resin layer RM2 may be filled into the second groove H2 (refer to FIGS. 8E and 8F). The forming of the second mother-sheet resin layer RM2 may be performed through a large-area coating process. In an embodiment, the forming of the second mother-sheet resin layer RM2 may be carried out by applying the resin through processes such as bar coating, slot-die coating, spray coating, or screen printing, for example. In an alternative embodiment, the forming of the second mother-sheet resin layer RM2 may be carried out by attaching a film including or consisting of resin.

Referring to FIGS. 7A, 8H, and 8I, the method for manufacturing the window in an embodiment of the inventive concept includes cutting the mother-sheet window PWM along the first division line CL to divide the plurality of windows WM (S200).

The mother-sheet window PWM may include the first mother-sheet resin layer RM1, the second mother-sheet resin layer RM2, and the third mother-sheet glass substrate PGM3. The window WM which is individually divided from the mother-sheet window PWM may include the above-described first resin layer RS1, second resin layer RS2, and glass substrate GL which are corresponding to the first mother-sheet resin layer RM1, the second mother-sheet resin layer RM2, and the third mother-sheet glass substrate PGM3. Additionally, as described above, the window WM in an embodiment may further include the window protective layer PL (refer to FIG. 5).

Referring to FIGS. 8H, 8I, and 9, the method for manufacturing the display device in an embodiment of the inventive concept may further include, coupling the display module DM to a lower portion of the window WM, after the cutting the mother-sheet window PWM along the first division line CL to divide the plurality of windows WM.

Referring to FIGS. 8H, 10A, and 10B, a method for manufacturing the display device in another embodiment of the inventive concept may include, after the forming of the mother-sheet window PWM, coupling a mother-sheet display substrate PDM to the lower portion of the mother-sheet window PWM to form a mother-sheet substrate PM, and cutting the mother-sheet substrate PM along the first division line CL to divide the plurality of display devices DD.

The mother-sheet display substrate PDM may include a plurality of display modules DM, which are divided by the first division line CL. The plurality of display modules DM may be coupled to the lower portions of windows WM so that the plurality of the display modules DM corresponds to the plurality of windows WM, respectively.

The mother-sheet substrate PM may include the mother-sheet window PWM, and the mother-sheet display substrate PDM. The display device DD, individually divided from the mother-sheet substrate PM, may include the above-described window WM and display module DM corresponding to the mother-sheet window PWM and the mother-sheet display substrate PDM.

The window in the embodiment of the inventive concept may include the glass substrate and the resin layer that fully covers the entirety of the surface of the glass substrate, which may improve reliability. Since the window in an embodiment includes the resin layer that fully covers the entirety of the surface of the glass substrate, the strength of the window may be enhanced. Additionally, the window in an embodiment may include the resin layer that covers the entirety of the surface of the glass substrate, particularly covers the side surface of the glass substrate, and may be manufactured through a process of applying resin to each mother-sheet unit. This may improve the uniformity of the resin layer applied to the glass substrate. As a result, the display device including the window in an embodiment of the inventive concept may have improved viewing reliability. Furthermore, the method for manufacturing the window, and the method for manufacturing the display device including the window in an embodiment of the inventive concept may include the dividing of the mother-sheet window after its formation and the forming of the resin layer on the top and bottom surfaces of the glass substrate when the mother-sheet window is formed. Therefore, the window having improved thickness uniformity and enhanced surface characteristics may be provided.

The display device in the embodiment of the inventive concept may include the resin layer that covers an entirety of the top surface, the bottom surface, and the side surface of the glass substrate, thereby improving the impact resistance and strength of the window including the glass substrate, which may enhance reliability.

The method for manufacturing the window in the embodiment of the inventive concept may include: separating after forming the mother-sheet window, and forming of the resin layer on the top and bottom surfaces of the glass substrate when forming the mother-sheet window, thereby providing a window with improved thickness uniformity and enhanced surface characteristics. Accordingly, the visibility of the user of the window manufactured through the method for manufacturing the window in the embodiment may be improved. Additionally, the method for manufacturing the display device in the embodiment of the inventive concept may manufacture the display device including the window with improved thickness uniformity and surface characteristics, thereby enhancing the reliability of the user.

Although the embodiments of the inventive concept have been described, it is understood that the inventive concept should not be limited to these embodiments, but various changes and modifications may be made by one ordinary skilled in the art within the spirit and scope of the inventive concept as hereinafter claimed.

Therefore, the technical scope of the inventive concept should not be limited to the content described in the detailed description of the specification but should be defined by the claims.

What is claimed is:

1. A display device comprising:
a display panel; and
a window disposed on the display panel, the window comprising:
a glass substrate comprising a top surface, a bottom surface facing the top surface in a thickness direction, and a side surface which is extended to the top surface and the bottom surface;
a resin layer which covers an entirety of the top surface, the bottom surface, and the side surface of the glass substrate; and
a window protective layer disposed on the resin layer.

2. The display device of claim 1, wherein the resin layer comprises:
a first resin layer which covers the top surface of the glass substrate; and
a second resin layer which covers the bottom surface and the side surface of the glass substrate.

3. The display device of claim 2, wherein the second resin layer comprises:
a (2-1)-th resin part disposed below the glass substrate to cover the bottom surface of the glass substrate; and
a (2-2)-th resin part disposed on a side portion of the glass substrate, and in contact with the side surface of the glass substrate,
wherein at least one portion of the first resin layer contacts the (2-2)-th resin part.

4. The display device of claim 3, wherein the first resin layer comprises:
a (1-1)-th resin part which is disposed on the glass substrate and covers the top surface of the glass substrate; and
a (1-2)-th resin part which extends in the thickness direction from the (1-1)-th resin part, and of which one side surface contacts at least a portion of the (2-2)-th resin part.

5. The display device of claim 4, wherein the (1-2)-th resin part is spaced apart from the (2-1)-th resin part in a cross-section.

6. The display device of claim 2, wherein a material contained in the first resin layer is identical to a material contained in the second resin layer.

7. The display device of claim 2, wherein a material contained in the first resin layer is different from a material contained in the second resin layer.

8. The display device of claim 2, wherein a first thickness of the glass substrate is greater than a second thickness of the first resin layer.

9. The display device of claim 1, wherein the resin layer comprises at least one of urethane resin, epoxy resin, polyimide resin, polyester resin, polyether resin, acrylate resin, or acrylonitrile-butadiene-styrene resin.

10. The display device of claim 2, wherein the window further comprises a fingerprint-resistant layer disposed on the window protective layer.

11. The display device of claim 1, further comprising an optical layer disposed on the display panel and the window.

12. An electronic device comprising:
a display device; and
a power module for supplying power to the display device, the display device comprising:
a display panel; and
a window disposed on the display panel, the window comprising:
a glass substrate comprising a top surface, a bottom surface facing the top surface in a thickness direction, and a side surface which is extended to the top surface and the bottom surface;
a resin layer which covers an entirety of the top surface, the bottom surface, and the side surface of the glass substrate; and
a window protective layer disposed on the resin layer.

13. A method for manufacturing a display device comprising a display module comprising a light-emitting element and a window disposed on the display module, the method comprising:
forming a mother-sheet window comprising a plurality of windows arranged in a first direction and a second direction intersecting the first direction, being divided by a first division line; and
cutting the mother-sheet window along the first division line to divide each of the plurality of windows,
wherein the forming the mother-sheet window comprises:
providing a first mother-sheet glass substrate comprising a preliminary glass substrate divided along the first division line;
irradiating laser onto the first mother-sheet glass substrate to correspond to the first division line, thereby defining a first groove, to form a second mother-sheet glass substrate;
forming a first mother-sheet resin layer on the second mother-sheet glass substrate;
etching the second mother-sheet glass substrate from a lower side to define a second groove corresponding to the first division line, thereby forming a third mother-sheet glass substrate; and
forming a second mother-sheet resin layer on a lower portion of the third mother-sheet glass substrate.

14. The method for claim 13, wherein the forming the second mother-sheet glass substrate further comprises:
chemically treating a top surface of the second mother-sheet glass substrate to increase a size of the first groove.

15. The method for claim 14, wherein the chemically treating the top surface of the second mother-sheet glass substrate to increase the size of the first groove comprises:
increasing in strength of the top surface of the second mother-sheet glass substrate.

16. The method for claim 13, wherein the forming the third mother-sheet glass substrate further comprises:
chemically treating a bottom surface of the third mother-sheet glass substrate to increase a size of the second groove.

17. The method for claim 16, wherein the chemically treating the bottom surface of the third mother-sheet glass substrate to increase the size of the second groove comprises:
increasing in strength of the bottom surface of the third mother-sheet glass substrate.

18. The method for claim 13, further comprising, after the forming the second mother-sheet resin layer, forming a mother-sheet window protective layer on the first mother-sheet resin layer.

19. The method for claim 13, further comprising, after dividing the plurality of windows, coupling the display module to a lower portion of the window.

20. The method for claim 13, further comprising, after forming the mother-sheet window:
providing a mother-sheet display substrate comprising a plurality of display modules which are divided through the first division line;
coupling the display module of the plurality of display modules to a lower portion of the mother-sheet window to form a mother-sheet substrate; and
cutting the mother-sheet substrate along the first division line to divide a plurality of display devices into each other so that the display device is provided from the plurality of display devices.
